(19) United States
(12) Patent Application Publication
(10) Pub. No.: US 2009/0278452 A1
(43) Pub. Date: Nov. 12, 2009

(54) Double-sided emission type organic light emitting diode display

(76) Inventor: Eun-Ah Kim, Yongin-City (KR)

Correspondence Address: LEE & MORSE, P.C., 3141 FAIRVIEW PARK DRIVE, SUITE 500, FALLS CHURCH, VA, 22042, US

(21) Appl. No.: 12/453,230

(22) Filed: May 4, 2009

(30) Foreign Application Priority Data
May 6, 2008 (KR) 10-2008-0041807

(51) Int. Cl. H01J 1/62

(52) U.S. Cl. 313/504

(57) ABSTRACT

A double-sided emission type OLED display includes a first substrate, a plurality of rear emission type OLEDs on the first substrate, a second substrate coupled to the first substrate, a plurality of front emission type OLEDs on the second substrate, and a third substrate coupled to the second substrate.

### BACKGROUND OF THE INVENTION

1. Field of the Invention

Example embodiments relate to an organic light emitting diode (OLED) display. More particularly, example embodiments relate to an OLED display having a double-sides emission type structure capable of emitting light in both directions to display images simultaneously on opposite surfaces.

2. Description of the Related Art

An OLED display having a double-sided emission type structure, i.e., a structure having a both-side emission, may emit light in two directions to display images on different surfaces of the OLED display simultaneously. For example, a conventional OLED display having a double-sided emission type structure may include a plurality of front emission type OLEDs on opposite surfaces of a single substrate, i.e., a front-emission structure. In another example, a conventional OLED display having a double-sided emission type structure may include a plurality of rear emission type OLEDs on facing surfaces of two substrates, so the rear emission OLEDs on the facing surfaces may directly face each other between the two substrates, i.e., a rear-emission structure.

Thin film transistors (TFTs) may be formed on a same surface of a substrate as the OLEDs to control driving of the OLEDs. Front emission means that light produced in an organic light emitting layer may be emitted in a front direction after passing through the TFTs, while rear emission means that the light produced in the organic light emitting layer may be emitted in a rear direction after passing through the TFTs.

In order to realize the conventional front emission type structure, however, a low temperature poly-silicon (LTPS) process may be required to form the TFTs on opposite surfaces of the single substrate, i.e., on the front and rear surfaces of the single substrate, thereby making the conventional front emission type structure complex and difficult to realize due to process limitations. Further, the conventional rear emission type structure may have a lower luminous efficiency than the front emission type structure, thereby exhibiting reduced display properties.

The above information disclosed in this Background section is only for enhancement of understanding of the background of the invention and therefore it contains information that does not form the prior art that is already known in this country to a person of ordinary skill in the art.

### SUMMARY OF THE INVENTION

Example embodiments are therefore directed an OLED display having a double-sided emission type structure, which substantially overcomes one or more of the shortcomings and disadvantages of the related art.

It is therefore a feature of an example embodiment to provide an OLED display having a double-sided emission type structure having a simplified construction.

It is another feature of an example embodiment to provide an OLED display having a double-sided emission type structure exhibiting improved display properties.

At least one of the above and other features may be realized by providing a double-sided emission type OLED display, including a first substrate, a plurality of rear emission type OLEDs formed on the first substrate, a second substrate coupled to the first substrate, a plurality of front emission type OLEDs formed on the second substrate, and a third substrate coupled to the second substrate.

The rear emission type OLEDs may be located on a surface of the first substrate facing the second substrate and the front emission type OLEDs may be located on a surface of the second substrate facing the third substrate. The first and third substrates may be transparent substrates, and the second substrate may be a non-transparent substrate. Alternatively, the first, second, and third substrates may be transparent substrates.

The double-sided emission type OLED display may further include a plurality of TFTs formed on the first substrate. Each of the rear emission type OLEDs may include a first pixel electrode electrically connected to a corresponding TFT, an organic light emitting layer, and a second pixel electrode. In addition, the first pixel electrode may be a transparent electrode and the second pixel electrode may be a reflective electrode. The double-sided emission type OLED display may further include a plurality of TFTs formed on the second substrate. Each of the front emission type OLEDs may include a first pixel electrode electrically connected to a corresponding TFT, an organic light emitting layer, and a second pixel electrode. In addition, the first pixel electrode may be a reflective electrode and the second pixel electrode may be a transparent electrode.

The second substrate may be between the first and third substrates. The rear emission type OLEDs may be between the first and second substrates, and the front emission type OLEDs may be between the second and third substrates. The first and second substrates may be spaced apart from each other to define an encapsulation space therebetween, the rear emission type OLEDs being in the encapsulation space. The rear emission type OLEDs may be spaced apart from the second substrate. All front and rear emission type OLEDs may be configured to be controlled by a single printed circuit board (PCB).

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a cross-sectional view of a double-sided emission type OLED display according to an exemplary embodiment;

FIG. 2 illustrates a circuit diagram of an equivalent circuit for driving an OLED of FIG. 1;

FIG. 3 illustrates a partially enlarged cross-sectional view of one rear emission type OLED of FIG. 1 connected to a corresponding TFT;

FIG. 4 illustrates a partially enlarged cross-sectional view of one front emission type OLED of FIG. 1 connected to a corresponding TFT of FIG. 2; and

FIG. 5 illustrates a cross-sectional view of first and second substrates of the OLED display of FIG. 1 connected via a FPCB.

### DETAILED DESCRIPTION OF THE INVENTION

Korean Patent Application No. 10-2008-0041807, filed on May 6, 2008, in the Korean Intellectual Property Office, and entitled: “Both-Sides Emission Type Organic Light Emitting Diode Display,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers, elements, and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together.

As used herein, the terms “a” and “an” are open terms that may be used in conjunction with singular items or with plural items.

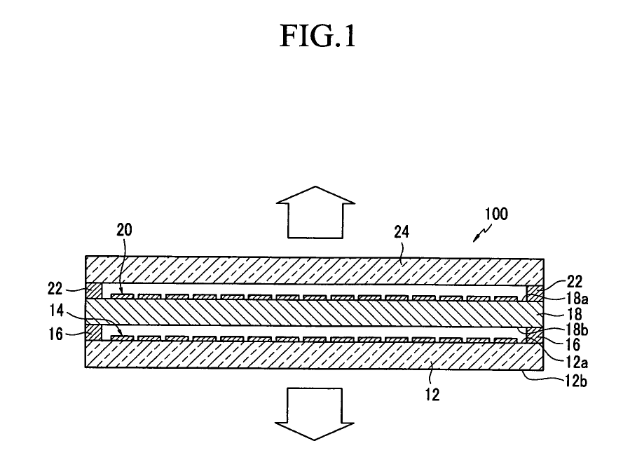

FIG. 1 illustrates a double-sided emission type OLED display, i.e., a double-sided emission type OLED display, according to an exemplary embodiment. Referring to FIG. 1, an OLED display 100 may include a first substrate 12, rear emission type OLEDs 14 provided at a display region of the first substrate 12, a second substrate 18 coupled to the first substrate 12 by a first sealant 16, front emission type OLEDs 20 provided at a display region of the second substrate 18, and a third substrate 24 coupled to the second substrate 18 by a second sealant 22. The first and second sealants 16 and 22 may be applied, e.g., along edges of respective substrates, and may be any suitable sealants. For example, each of the first and second sealants 16 and 22 may be thicker than the rear and front emission type OLEDs 14 and 20, respectively, so the rear and front emission type OLEDs 14 and 20 may be spaced apart from respective second and third substrates 18 and 24, respectively.

The first substrate 12 may be formed of a transparent material. The first substrate 12 may include a first surface 12a, i.e., a surface facing the second substrate 18, and a second surface 12b, i.e., an external surface of the OLED display 100.

The rear emission type OLEDs 14 may be positioned on the first surface 12a of the first substrate 12. For example, as illustrated in FIG. 1, the rear emission type OLEDs 14 may be arranged on the first substrate 12 to be adjacent to each other along a horizontal direction, e.g., the rear emission type OLEDs 14 may be spaced apart from each along the horizontal direction. Light produced by the rear emission type OLEDs 14 may be emitted outside the OLED display 100 through the first substrate 12, as illustrated by an arrow pointing in a downward direction with respect to the first substrate 12 in FIG. 1.

The second substrate 18 may be any suitable substrate, and may be formed of a transparent material or a non-transparent material, as will be discussed in more detail below. The second substrate 18 may include a first surface 18a, i.e., a surface facing the third substrate 24, and a second surface 18b, i.e., a surface facing the first substrate 12. The first and second substrates 12 and 18 may be attached, so the rear emission type OLEDs 14 may be between the first and second substrates 12 and 18.

The front emission type OLEDs 20 may be positioned on the first surface 18a of the second substrate 18. For example, as illustrated in FIG. 1, the front emission type OLEDs 20 may be arranged on the second substrate 18 to be adjacent to each other along a horizontal direction, e.g., the front emission type OLEDs 20 may be spaced apart from each along the horizontal direction. For example, the front emission type OLEDs 20 may be aligned with the rear emission type OLEDs 14. Light produced by the front emission type OLEDs 20 may be emitted outside the OLED display 100 through the third substrate 24, as illustrated by an arrow pointing in an upward direction with respect to the third substrate 24 in FIG. 1.

The first and third substrates 12 and 24 may be formed of a transparent material, and the second substrate 18 may be formed of a transparent or non-transparent material. When the second substrate 18 is formed of a non-transparent material, light leaking from the rear emission type OLEDs 14 toward the third substrate 24 and light leaking from the front emission type OLEDs 20 toward the first substrate 12 may be blocked. When the second substrate 18 is formed of a transparent material, a light absorption member, e.g., a black matrix layer, may be formed on the first surface 12a of the first substrate 12 between adjacent rear emission type OLEDs 14 and/or on the first surface 18a of the second substrate 18 between adjacent front emission type OLEDs 20 to block or substantially minimize light leaking from the rear emission type OLEDs 14 and/or the front emission type OLEDs 20 toward corresponding substrates, e.g., through a region between adjacent OLEDs 14 and 20 and/or through a dead space where the OLEDs 14 and 22 are not formed.

The second substrate 18 may be coupled to the first substrate 12 to define an encapsulation space therebetween, e.g., the second substrate 18 may function as an encapsulation substrate of the first substrate 12. The third substrate 24 may be coupled to the second substrate 18, so the front emission type OLEDs 20 may be therebetween. Accordingly, the third substrate 24 may function as an encapsulation substrate of the second substrate 18.

The OLED display 100 may further include a first moisture absorbent layer (not shown) on a second surface 18b of the second substrate 18, i.e., a surface facing the first substrate 12. The OLED display 100 may further include a second moisture absorbent layer (not shown) on a surface of the third substrate 24, i.e., a surface facing the second substrate 18. The OLED display 100 may further include a polarizing plate (not shown) on outer surfaces of the first and third substrates 12 and 24, e.g., on the second surface 12b of the first substrate 12.

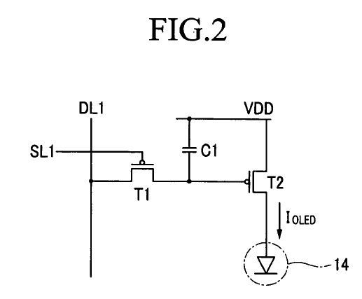

The front emission type OLEDs 20 may have excellent light emission efficiency, and may be disposed at a main display side of the OLED display 100, e.g., the main display side of the OLED display 100 may correspond to the third substrate 24. The rear emission type OLEDs 14 and the front emission type OLEDs 20 may be active matrix OLEDs each having a driving circuit unit, as will be discussed in more detail with reference to FIG. 2.

An OLED display having a double-sided emission type structure according to example embodiments may include a plurality of front and rear emission type OLEDs on first and second substrates, respectively. The OLEDs may be arranged so each type of OLEDs may be on a different substrate, and each type of the OLEDs may emit light in a different direction. Formation of the different OLEDs on different substrates may facilitate the manufacturing process, e.g., may eliminate difficulties associated with the LTPS process. Further, the front emission type OLEDs 20 may exhibit excellent luminous efficiency, thereby substantially improving display properties of the OLED display 100.

FIG. 2 illustrates an equivalent circuit of a rear emission type OLED 14 in the OLED display 100 of FIG. 1. Referring to FIG. 2, a driving circuit unit for controlling driving of the rear emission type OLED 14 may include at least two TFTs, e.g., a first TFT T1 for switching and a second TFT T2 for driving, and a capacitor C1. It is noted that the number of the TFTs and capacitors in the driving circuit may be any suitable number not limited to the above, e.g., two or more TFTs and one or more capacitors may be provided.

As illustrated in FIG. 2, the first TFT T1 may be connected to scan and data lines SL1 and DL1. The first TFT T1 may transfer a data voltage, which may be input to the data line DL1 according to a switching voltage input to the scan line SL1, to the second TFT T2.

The storage capacitor C1 may be connected to the first TFT T1 and to a power line VDD. The storage capacitor C1 may store a voltage corresponding to a difference between the voltage from the first TFT T1 and the voltage from the power line VDD.

The second TFT T2 may be connected to both the power line VDD and the storage capacitor C1 to supply an output current I_{OLED}, which may correspond to a square of a difference between a voltage stored in the storage capacitor C1 and a threshold voltage, to the rear emission type OLED 14 so that the rear emission type OLED 14 may emit light corresponding to the output current I_{OLED}.

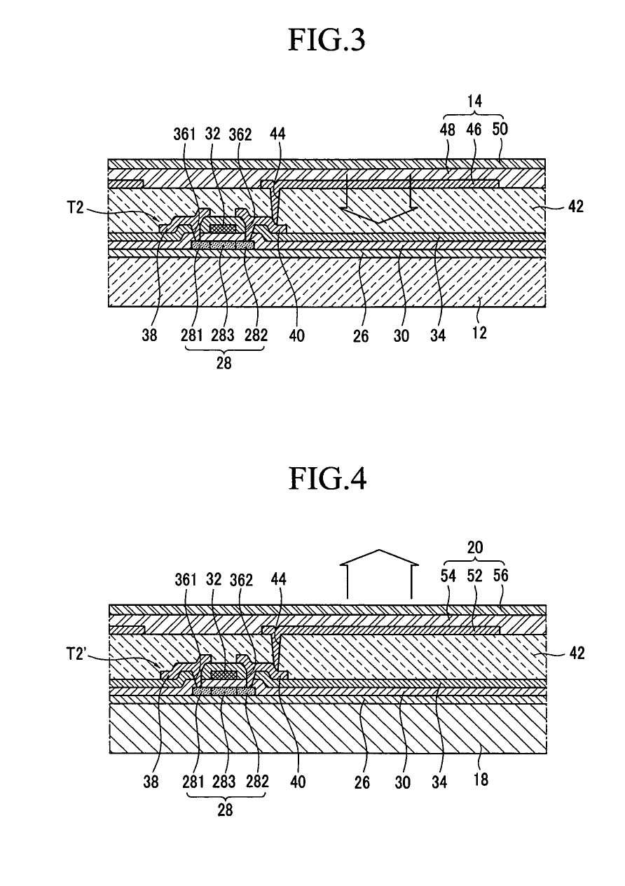

FIG. 3 illustrates an enlarged cross-section of one rear emission type OLED 14 in the OLED display 100 of FIG. 1 connected to the second TFT T2 of FIG. 2. Referring to FIG. 3, the OLED 14 and the second TFT T2 may be on the first substrate 12. As further illustrated in FIG. 3, a buffer layer 26 may be formed on the first substrate 12, i.e., between the first substrate 12 and the second TFT T2, and a passivation layer 42 may be formed between the second TFT T2 and the rear emission type OLED 14.

The buffer layer 26 may prevent dispersion of moisture or impurities, e.g., generated on the first substrate 12, into the second TFT T2. Further, the buffer layer 26 may adjust a thermal transferring speed during a crystallization process of an active layer 28 of the second TFT T2, so the crystallization of the active layer 28 may be effectively realized. The buffer layer 26 may be a single layer formed of, e.g., a silicon nitride, or a multi-layer having, e.g., a silicon nitride layer and a silicon oxide layer.

As further illustrated in FIG. 3, the TFT T2 may include the active layer 28, a gate dielectric 30, a gate electrode 32, and source/drain electrodes 38 and 40.

The active layer 28 may be formed on the buffer layer 26. The active layer 28 may include a source region 281, a drain region 282, and a channel region 283 between the source and drain regions 281 and 282. The active layer 28 may be formed by depositing amorphous silicon, crystallizing the deposited amorphous silicon, and patterning the crystallized silicon.

The gate dielectric 30 may be formed on the buffer layer 26 to cover the active layer 28, and the gate electrode 32 may be formed on the gate dielectric 30, i.e., in a region corresponding to the channel region 283, so the gate dielectric 30 may be between the active layer 28 and the gate electrode 32. The gate electrode 32 may be formed of one or more of, e.g., MoW, Al, Cr, or Al/Cr. The source and drain regions 281 and 282 of the active layer 28 may be formed by doping impurities in the active layer 28 by using the gate electrode 32 as a mask.

An interlayer dielectric 34 may be formed on the gate dielectric 30 to cover the gate electrode 32. A first contact hole 361 for exposing the source region 281 and a second contact hole 362 for exposing the drain region 282 may be formed through the interlayer dielectric 34 and the gate dielectric 30.

The source electrode 38 may be formed on the interlayer dielectric 34, and a portion of the source electrode 38 may fill the first contact hole 361 to electrically connect to the source region 281 of the active region 28. The drain electrode 40 may be formed on the interlayer dielectric 34, and a portion of the drain electrode 40 may fill the second contact hole 362 to electrically connect to the drain region 282 of the active region 28.

The passivation layer 42 may be formed on the interlayer dielectric 34, and may cover the source and drain electrodes 38 and 40. The passivation layer 42 may protect the second TFT T2 disposed thereunder. The passivation layer 42 may be formed of an organic material, e.g., one or more of benzocyclobutene (BCB), an acryl-based organic material, a polyimide-based organic material, and so forth, and/or an inorganic material, e.g., silicon oxinitride (SiNₓ). The passivation layer 42 may be a single layer or a multi-layer. The passivation layer 42 may be provided with a via-hole 44 exposing the drain electrode 40.

The rear emission type OLED 14 may be eclectically connected to the second TFT T2 through the via-hole 44 in the passivation layer 42. The rear emission type OLED 14 may include a first pixel electrode 46, an organic light emitting layer 48, and a second pixel electrode 50.

The first pixel electrode 46 may be formed on the passivation layer 42, so a portion of the first pixel electrode 46 may fill the via-hole 44 and contact the drain electrode 40. The organic light emitting layer 48 and the second pixel electrode 50 may be formed sequentially on the first pixel electrode 46.

The first pixel electrode 46 may function as an anode electrode. The first pixel electrode 46 may be a transparent electrode formed of, e.g., one or more of ITO, IZO, ZnO, or In₂O₃.

The second pixel electrode 50 may function as a cathode electrode. The second pixel electrode 50 may be a reflective electrode formed of, e.g., one or more of Li, Ca, LiF/Ca, LiF/Al, Al, Ag, Mg.

The organic light emitting layer 48 may include a hole injection layer, a hole transport layer, an electron transport layer, and an electron injection layer. As the first pixel electrode 46 is transparent and the second pixel electrode 50 is reflective, light produced by the organic light emitting layer 48 may be reflected by the second pixel electrode 50 toward the transparent first pixel electrode 46, so light produced in the rear emission type OELD 14 may pass through the first substrate 12. Therefore, images realized by the rear emission type OLEDs 14 may be projected to an outside of the OLED display 100 through the first substrate 12.

FIG. 4 illustrates an enlarged cross-section of one front emission type OLED 20 in the OLED display 100 of FIG. 1 connected to a second TFT T2′. In this respect, it is noted that the front emission type OLEDs 20 may be provided on the second substrate 18 with a driving circuit unit substantially identical to the driving circuit unit of the rear emission type OLEDs 14 illustrated in FIG. 2, so the second TFT T2′ in FIG. 4 may be substantially identical to the second TFT T2 in FIG. 3.

As illustrated in FIG. 4, the front emission type OLED 20 may include a first pixel electrode 52 formed on the passivation layer 42, and a portion of the first pixel electrode may fill the via-hole 44 to contact the drain 40 of the second TFT T2′. An organic light emitting layer 54 and a second pixel electrode 56 may be formed sequentially on the first pixel electrode 52. The passivation layer 42 may be between the second TFT T2′ and the first pixel electrode 52.

The first pixel electrode 52 may function as an anode electrode. The first pixel electrode 52 may be a reflective electrode, and may include a reflective layer formed of, e.g., one or more of Ag, Mg, Al, Pt, Pd, Au, Ni, Nd, Ir, Cr, and so forth, and a transparent layer formed of, e.g., one or more of ITO, IZO, ZnO, or In₂O₃.

The second pixel electrode 56 may function as a cathode electrode. The second pixel electrode 56 may be a transparent electrode formed by depositing, e.g., one or more of Li, Ca, LiF/Ca, LiF/Al, Al, Ag, Mg, and so forth, and forming a sub-electrode layer or a bus electrode line of, e.g., one or more of ITO, IZO, ZnO, and In₂O₃.

As the first pixel electrode 52 is a reflective electrode and the second pixel electrode 56 is a transparent electrode, the light emitted from the organic light emitting layer 54 therebetween may be reflected by the first pixel electrode 52 toward the second pixel electrode 56 to pass through the third substrate 24, as illustrated in FIGS. 1 and 4. Therefore, the image produced by the front light emission type OLEDs 20 may be projected to an outside of the OLED display 100 through the third substrate 24.

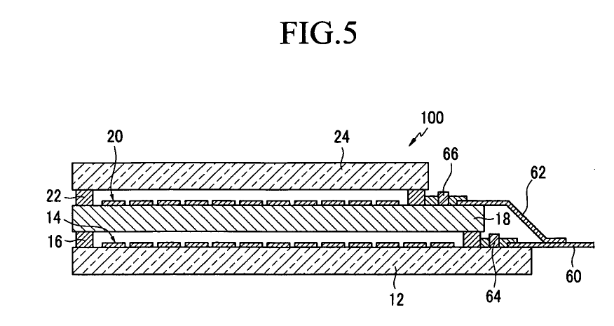

FIG. 5 illustrates a cross-sectional view of a connection state of a flexible printed circuit board (FPCB) to the first and second substrates 12 and 18 of the OLED display 100 of FIG. 1. Referring to FIG. 5, a first integrated circuit 64 may be installed on the first substrate 12 to drive the rear emission type OLEDs 14, and a second integrated circuit 66 may be installed on the second substrate 18 to drive the front emission type OLEDs 20. As illustrated in FIG. 5, lengths of the first, second, and third substrates 12, 18, and 24 may be modified to facilitate positioning and connection of the first and second integrated circuits 64 and 66. For example lengths of the first through third substrates may be different from each other, e.g., the first substrate 12 may be longer than the second substrate 18 as measured along the horizontal direction and the second substrate 18 may be longer than the third substrate 24 as measured along the horizontal direction. The three substrates may be aligned in any suitable configuration, e.g., all three substrates may be aligned at corresponding first edges thereof so the first and second integrated circuits 64 and 66 may be positioned at second edges, i.e., edges opposite respective first edges, of respective first and second substrates 12 and 18.

As illustrated in FIG. 5, the first integrated circuit 64 may be on the first surface of the first substrate 12, i.e., on a same surface as the rear emission type OLEDs 14, and the second integrated circuit 66 may be on the first surface of the second substrate 18, i.e., on a same surface as the front emission type OLEDs 20. For example, the second integrated circuit 66 may overlap a portion of the rear emission type OLEDs 14. The first and second integrated circuits 64 and 66 may be electrically connected to pads (not shown) or to first and second FPCBs 60 and 62, respectively. The first and second FPCBs 60 and 62 may be connected to each other, as further illustrated in FIG. 5. The first FPCB 60 may be connected to a printed circuit board (PCB) (not shown).

Therefore, in the double-sided emission type OLED display 100 according to example embodiments, electrical signals for driving both the rear and front emission type OLEDs 14 and 20 may be provided through a single PCB. In addition, a circuit including the first and second FPCBs 60a and 62 and the PCB may be formed in a simple structure, thereby simplifying the manufacturing process.

As described above, as the front and rear emission type OLEDs 14 and 20 are formed on different substrates according to example embodiments, the OLED display 100 may be easily manufactured without any process difficulties. For example, the structure of the OLED display 100 according to example embodiments may be designed to eliminate obstacles in performing the LTPS process for forming TFTs for driving the OLEDs. In addition, since the front emission type OLEDs 20 exhibit excellent luminous efficiency, the luminous efficiency and luminance of the OLED display 100 may be substantially improved.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A double-sided emission type organic light emitting diode (OLED) display, comprising:
a first substrate;
a plurality of rear emission type OLEDs on the first substrate;
a second substrate coupled to the first substrate;
a plurality of front emission type OLEDs on the second substrate; and
a third substrate coupled to the second substrate.

2. The double-sided emission type OLED display as claimed in claim 1, wherein the rear emission type OLEDs are on a first surface of the first substrate and the front emission type OLEDs are on a first surface of the second substrate, the first surface of the first substrate facing the second substrate, and the first surface of the second substrate facing the third substrate.

3. The double-sided emission type OLED display as claimed in claim 1, wherein the first and third substrates are transparent substrates and the second substrate is a non-transparent substrate.

4. The double-sided emission type OLED display as claimed in claim 1, wherein the first, second, and third substrates are transparent substrates.

5. The double-sided emission type OLED display as claimed in claim 1, further comprising a plurality of thin film transistors (TFTs) on the first substrate,
wherein each of the rear emission type OLEDs includes a first pixel electrode, an organic light emitting layer, and a second pixel electrode; and
wherein the first pixel electrode is a transparent electrode electrically connected to a corresponding TFT and the second pixel electrode is a reflective electrode.

6. The double-sided emission type OLED display as claimed in claim 1, further comprising a plurality of thin film transistors (TFTs) on the second substrate,
wherein each of the front emission type OLEDs includes a first pixel electrode, an organic light emitting layer, and a second pixel electrode; and
wherein the first pixel electrode is a reflective electrode electrically connected to a corresponding TFT and the second pixel electrode is a transparent electrode.

7. The double-sided emission type OLED display as claimed in claim 1, wherein the second substrate is between the first and third substrates.

8. The double-sided emission type OLED display as claimed in claim 7, wherein the rear emission type OLEDs are between the first and second substrates, and the front emission type OLEDs are between the second and third substrates.

9. The double-sided emission type OLED display as claimed in claim 1, wherein the first, second, and third substrates are spaced apart from each other, the rear emission type OLEDs being in a space between the first and second substrates, and the front emission type OLEDs being in a space between the second and third substrates.

10. The double-sided emission type OLED display as claimed in claim 9, wherein the rear emission type OLEDs are spaced apart from the second substrate.

11. The double-sided emission type OLED display as claimed in claim 1, wherein all front and rear emission type OLEDs are configured to be controlled by a single printed circuit board (PCB).
